(19) United States
(12) Patent Application Publication
(10) Pub. No.: US 2008/0064182 A1
(43) Pub. Date: Mar. 13, 2008

(54) PROCESS FOR HIGH TEMPERATURE LAYER TRANSFER

(76) Inventor: Xavier Hebras, Grenoble (FR)

Correspondence Address: WINSTON & STRAWN LLP;PATENT DEPARTMENT, 1700 K STREET, N.W., WASHINGTON, DC, 20006, US

(21) Appl. No.: 11/621,838

(22) Filed: Jan. 10, 2007

(30) Foreign Application Priority Data
Sep. 12, 2006 (FR) 0653685

(51) Int. Cl. H01L 21/30

(52) U.S. Cl. 438/455

(57) ABSTRACT

The invention concerns a method for transferring a thin layer from a donor wafer onto a receiving wafer by implanting at least one atomic species into the donor wafer to form a weakened zone therein, with the weakened zone being including microcavities or platelets therein, and the thin layer being defined between the weakened zone and a surface of the donor wafer; molecular bonding of the surface of the donor wafer onto a surface of the receiving wafer; splitting the thin layer at the zone of weakness by heating to a high temperature to transfer the thin layer to the receiving substrate; and treating the donor wafer to block or limit the formation of microcavities or platelets by trapping the atoms of at least one of the implanted atomic species at least until a certain release temperature is reached during the splitting. This method enables bonding energy to be reinforced adjacent the layer to be transferred and hence limits defects in the resulting heterostructure.

### FIELD OF THE INVENTION

The present invention relates to a method for transferring a layer from a donor substrate onto a receiving substrate used for the fabrication of heterostructures such as structures of SeOI type (“Semiconductor on Insulator”) for electronic, microelectronic and optoelectronic applications.

### BACKGROUND OF THE INVENTION

One well-known technology for producing heterostructures via layer transfer is the SMART-CUT® technology. An example of application of SMART-CUT® technology is described in particular in document U.S. Pat. No. 5,374,564 or in the article by A. J. Auberton-Herve et al titled “Why can Smart-Cut Change the Future of Microelectronics?”, Int. Journal of High Speed Electronics and Systems, Vol. 10, No 1, 2000, p. 131-146. This technology uses the following steps:
a) bombarding the surface of a donor substrate (e.g. in silicon) with light ions of hydrogen or rare gas type (e.g. hydrogen and/or helium), to implant these ions in the substrate in sufficient concentration, the implanted area allowing the creation of a breaking layer through the formation of microcavities or platelets during splitting annealing,
b) closely contacting (i.e., bonding) this surface of the donor substrate with a receiving substrate, and
c) splitting annealing which, through an effect of crystal rearrangement and pressure in the microcavities or platelets formed from the implanted species, causes breaking or cleavage at the implanted layer to obtain a heterostructure resulting from the detachment and transfer of the donor substrate onto the receiving substrate.

However, the heterostructures so obtained have defects not only on the surface of the transferred layer but also at the interfaces of the layers forming the heterostructure.

Different types of surface defects may appear after the transfer of a layer onto a receiving substrate. These defects include: surface roughness, non-transferred areas (NTAs), blisters, voids, voids of COV type (Crystal Orientated Voids), etc.

These defects have various causes such as poor transfer, the presence of underlying defects in the various layers of the structure, the quality of bonding at the interfaces or merely the different steps which must be implemented to fabricate said structures (implanting species, heat treatment, etc.).

To overcome these problems, various techniques have been developed such as low temperature annealing for example (particularly described in document U.S. 2006/0040470), plasma treatments enabling an increase in bonding energy at the interfaces and leading to separation of the layer to be transferred with few defects. It is known that, at the time of transfer, the greater the bonding energy between the donor substrate and the receiving substrate, the fewer defects in the resulting heterostructure. The solutions developed such as plasma treatment of the surface or surfaces to be bonded, make it possible to increase bonding energy while limiting the temperature of heat treatment applied to achieve delamination so as to limit the diffusion of contaminants.

Similarly, in document JP 2005085964 it is sought to strengthen bonding energy before splitting of the layer to be transferred by using a helium implantation step and then applying splitting annealing at high temperature in ranges of 800° C. to 1100° C.

Another process reported in document U.S. Pat. No. 6,756,286 is intended to improve the surface condition of the transferred layer after it has been split. It consists of forming an inclusion layer to confine the gas species derived from implantation in order to reduce surface roughness of the separated layer by reducing implantation doses and the heat schedule.

Finally, in document U.S. Pat. No. 6,828,216 it is proposed to apply splitting annealing in two phases, the first phase making it possible to achieve initiated splitting of the layer to be transferred using an approximate standard range of 400 to 500° C.; the second phase allowing completion of splitting to obtain a surface condition of good quality with final annealing temperatures in the region of 600 to 800° C.

However, these current techniques are not suitable for all heterostructures of SeOI type (Semiconductor on insulator), and in particular for those containing a thin insulating oxide layer (UTBOX “Ultra Thin Buried Oxide Layer”) or even not containing any oxide layer e.g. heterostructures of DSB type for example (“Direct Silicon Bonding”).

With this type of heterostructure, the oxide layer being thin or non-existent, the diffusing species (e.g. gases) are not trapped in the thickness of the oxide layer and can be the cause of numerous defects within the heterostructure.

### SUMMARY OF THE INVENTION

To overcome the above-cited disadvantages, the present invention puts forward a solution, which, at the time of transferring a layer between a donor substrate and a receiving substrate, enables bonding energy to be reinforced adjacent the layer to be transferred and hence limits defects in the resulting heterostructure.

For this purpose, the invention concerns a method for transferring a thin layer from a donor wafer onto a receiving wafer including implanting at least one atomic species into the donor wafer to form a weakened zone therein, with the weakened zone being including microcavities or platelets therein, and the thin layer being defined between the weakened zone and a surface of the donor wafer. The method further includes molecular bonding of the surface of the donor wafer onto a surface of the receiving wafer, splitting the thin layer at the zone of weakness by heating to a high temperature to transfer the thin layer to the receiving substrate, and treating the donor wafer to block or limit the formation of microcavities or platelets by trapping the atoms of at least one of the implanted atomic species at least until a certain release temperature is reached during the splitting. The treating of the donor wafer can be conducted performed before or after implanting.

Therefore, by treating the donor wafer to trap the atoms of the implanted atomic species, the inventive method makes it possible to create a new reaction pathway for the implanted atomic species in order to delay the separation of the thin layer to be transferred. The implanted atoms, intended to form the weakened zone and to cause separation of the layer to be transferred during splitting annealing, are provisionally trapped, and are only released to form microcavities or platelets when a high release temperature is applied. As explained below, it has been found that the higher the temperature the more the bonding power is reinforced. This reinforcement is even greater when using temperatures higher than temperatures usually used for splitting annealing operations.

With silicon for example, the trapping treatment is chosen so as to require a certain release temperature higher than temperatures usually used for splitting annealing, i.e. a temperature higher than at least 500° C. Therefore, by releasing the atoms responsible for splitting at a temperature higher than the usual temperature used for splitting, the atoms only carry out their role in separating the layer to be transferred over and above a temperature at which bonding energy is greater, making it possible to obtain a heterostructure with fewer defects.

According to a first approach of the invention, the treating is conducted by inserting into the donor wafer at least one ion species that has the ability to react with the implanted atomic species.

Therefore, by setting up bonds and/or interactions between the two species, the reactive species will form stable complexes with the atomic species used for splitting. The development of the implanted atoms able to cause splitting is then delayed for as long as they are not released from the stable complexes. To separate them from those of the reactive species, heat treatment must be applied at a higher temperature (between approximately 550° C. and 800° C.) than usual to cause splitting at the breaking layer. The application of a higher temperature during splitting of the layer to be transferred makes it possible to reinforce bonding energy and hence to limit the onset of defects after transfer.

According to one aspect of the invention, the insertion of the one or more ion species able to react with the species implanted for splitting is achieved by implanting ions in the donor substrate. The species able to react with the species implanted for splitting may be chosen in particular from among fluorine, nitrogen and carbon.

According to another aspect of the invention, the insertion of the one or more ion species able to react with the atomic species is made by forming a doped layer in the donor substrate, this layer preferably being inserted prior to implanting the atomic species. This layer may be made by depositing or implanting. The depositing of the doped layer can be made in particular by Plasma Chemical Vapor Deposition (PCVD) or by Low Pressure Chemical Vapor Deposition (LPCVD). With a donor substrate in silicon, the layer is doped with carbon, boron, phosphorus, arsenic, indium or gallium. Generally, the dopants are chosen in relation to the type of donor substrate to be treated. Preferably, the atomic species is hydrogen.

According to a second approach of the invention, the treating the donor wafer to trap the implanted atomic species is achieved by the formation of defects in the donor substrate. This formation is made by inserting ion species in the donor substrate, for example by helium ion implantation, said implantation being followed by a heat treatment to form cavities in the area implanted with helium.

The cavities so formed will trap the implanted atoms for subsequent delamination up to a release temperature that is higher than the usual splitting temperature so that the separation of the layer to be transferred will occur at a higher temperature at which bonding energy is reinforced, this temperature lying between approximately 550° C. and 800° C.

The implanting of helium ions can be conducted with an implantation energy of between 10 and 150 keV and an implanting dose of between 1×10¹⁶ atoms/cm² and 5×10¹⁷ atoms/cm². The heat treating to form cavities can be conducted at a temperature of between 450° C. and 1000° C. for a time of between 30 minutes and 1000 minutes. Preferably, the heat treating is performed at a temperature of approximately 700° C. for a time of approximately 30 minutes. The implanted atomic species preferably includes hydrogen and helium.

According to one aspect of the invention, the donor substrate is in semi-conductor material. It can in particular be a substrate of silicon or germanium, or silicon-germanium, or gallium nitride, or gallium arsenide, or silicon carbide. It may also be an insulating material or ferromagnetic, piezoelectric and/or pyroelectric materials (e.g. Al₂O₃, LiTa0₃).

Optionally, the bonding surfaces of the donor substrate and of the receiving substrate are preferably previously treated to render them hydrophobic, the reinforcement of bonding energy being even greater in the event of hydrophobic bonding.

### BRIEF DESCRIPTION OF THE DRAWINGS

The characteristics and advantages of the present invention will become better apparent from the following description given by way of example and non-limiting, with respect to the appended Figs. in which:

FIG. 1 shows the variations in bonding energy in relation to temperature

FIGS. 2A to 2E are schematic cross-section views showing the transfer of a Si layer according to one embodiment of the invention,

FIG. 3 is a flow chart indicating the steps implemented in FIGS. 2A to 2E,

FIGS. 4A to 4F are schematic cross-section views showing the transfer of a Si layer according to another embodiment of the invention,

FIG. 5 is a flow chart of the steps conducted in FIGS. 4A to 4F,

FIG. 6 shows the formation of cavities in a Si substrate after helium implantation and heat treatment,

FIG. 7 shows a thick layer of small cavities formed in a Si substrate after helium implantation and heat treatment,

FIG. 8 shows a layer in which hydrogen ions implanted in a Si substrate are trapped between and around cavities formed after helium implantation and heat treatment.

### DETAILED DESCRIPTION OF THE PREFERRED EMBODIMENTS

The present invention applies to any thin layer transfer method using at least one atomic species implantation of a donor substrate to delimit a thin layer to be transferred by a breaking plane, bonding of the implanted donor substrate onto a receiving substrate, and application of a heat treatment called splitting annealing at high temperature to separate the layer to be transferred from the donor substrate as in SMART-CUT® technology.

The principle of the invention consists of increasing the temperature of splitting annealing required for the formation and development of a weakened zone, comprised of microcavities or platelets, to cause a fracture in the donor substrate so as to increase the bonding energy at the interface between the donor substrate and receiving substrate.

Typically, splitting annealing in SMART-CUT® technology for substrates of silicon type is conducted over a temperature range of between 400° C. and 500° C. for a determined time (the temperature/time pair corresponds to the heat schedule for splitting annealing).

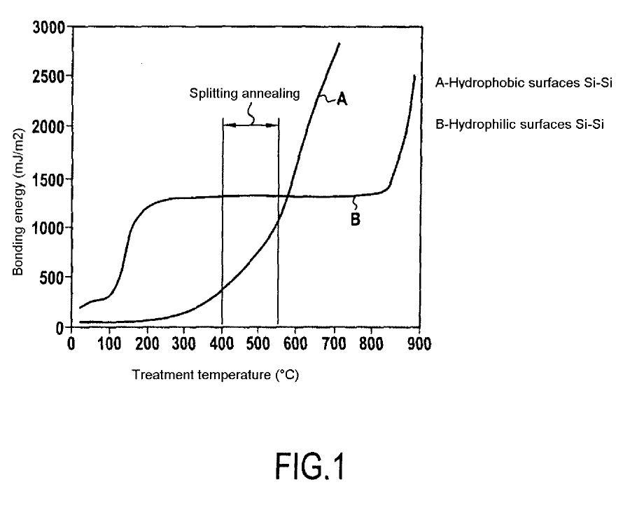

In the work “Semiconductor wafer bonding: Science and technology” by Q. Y. Tong and U. Gosele, The Electrochemical Society, Pennington, N.J., 1999, pages 117-118, the variations in bonding energy in relation to temperature were measured. The results obtained by the authors of this work are given in FIG. 1 which shows the variations in bonding energy between two silicon substrates in relation to temperature, for silicon substrates assembled either by hydrophobic bonding (curve A) or hydrophilic bonding (curve B).

With reference to FIG. 1 it is ascertained that:
for hydrophilic bonding, the energy at the bonding interface is stable at around 1250 mJ/m² from 200° C. onwards, then increases rapidly over and above 800° C., while
for hydrophobic bonding, bonding energy increases exponentially with temperature.

Therefore, by increasing the heat treatment temperature during splitting, the bonding energy is reinforced at the time of layer transfer, making it possible to obtain separation of a layer having few defects.

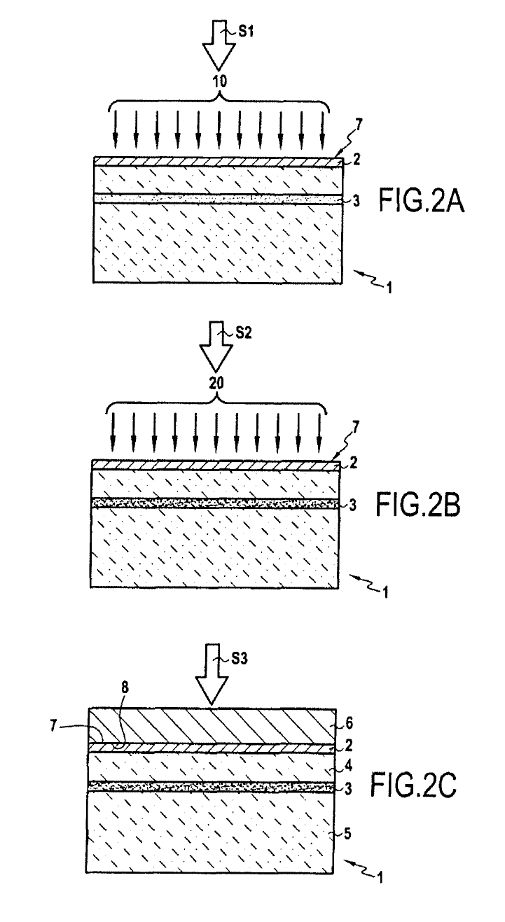

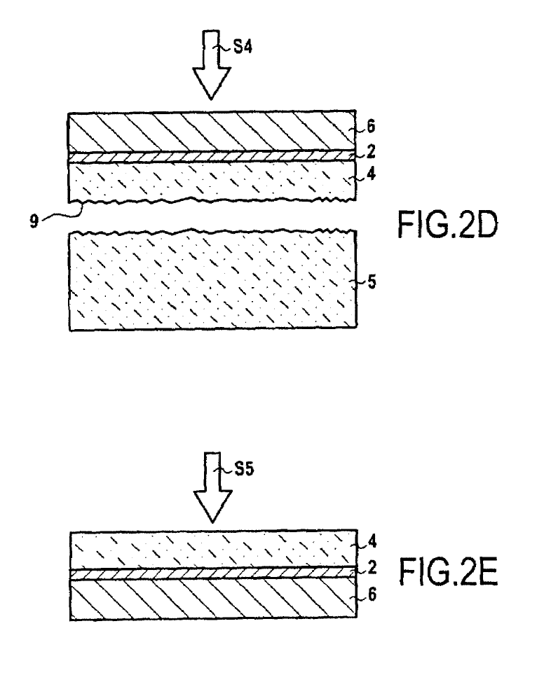

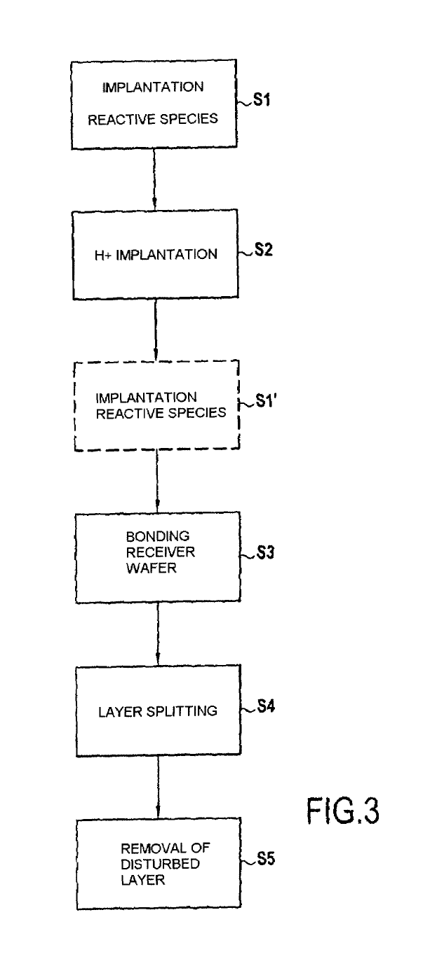

With reference to FIGS. 2A to 2E and 3, a method is described for transferring a layer according to one embodiment of the invention.

In this embodiment, the starting substrate or donor substrate 1 consists of a wafer of monocrystalline silicon coated with an insulating layer of silicon oxide (SiO₂)2, obtained by thermal oxidation and having a thickness of approximately 300 Å.

During a first so-called implantation step of ion or reactive species (step S1), the wafer 1 is subjected to ion bombardment 10 of atoms through the planar surface 7 of the wafer comprising the SiO₂ layer 2. According to the invention, the implanted atoms are atoms chosen from among species that are highly reactive with the species used during subsequent implantation to achieve splitting of the layer. By way of example, with the SMART-CUT® technology, the implantation leading to splitting is typically performed with hydrogen atoms. In this case, the implantation of reactive species can be conducted using fluorine, nitrogen or carbon atoms in particular, which species are known to be highly reactive with hydrogen.

In the present example, it is considered that the donor wafer is implanted with hydrogen atoms for the splitting implantation step, and with fluorine atoms for the reactive species implantation step.

During the reactive species implantation step, fluorine atoms are implanted with an implanting energy of between 80 and 280 keV and an implanting dose of between 5×10¹⁴ and 2×10¹⁵ atoms/cm². This dose is calculated to avoid any amorphisation of the wafer during implantation. With these implanting conditions it is possible, at a determined depth of the wafer 1, to create a concentration layer of fluorine atoms 3 (FIG. 2A).

The implanting dose is chosen so that the concentration of fluorine atoms in layer 3 is sufficient to create a layer of auxiliary defects within the donor wafer, able to provisionally trap (i.e. up to a certain temperature) the hydrogen atoms that are subsequently implanted during the splitting implantation step. Implanting dose and energy are also chosen so that the reactive species of layer 3 lie in an area adjacent to the area where the hydrogen will be implanted during the atomic species implantation step intended to form a breaking layer for subsequent splitting.

With fluorine implantation the auxiliary defects formed may for example be cavities, defects of type {113}, dislocation loops which will allow the subsequently implanted hydrogen to be retained by forming stable complexes between the fluorine and hydrogen atoms, such as H—F bonds.

Similarly, implantation conducted using carbon or nitrogen atoms leads to the formation of auxiliary defects in the donor wafer, and will allow the trapping of subsequently implanted hydrogen atoms through the formation of stable complexes such as C—H or N—H bonds.

Once the implanting of ion or reactive species is completed, the implantation step usually performed is implemented to achieve splitting of the layer from the donor wafer (step S2, FIG. 2B).

The reactive species implantation step can also be conducted after the splitting implantation step (step S1′).

During this splitting implantation step, the wafer 1 is subjected to ion bombardment 20 of H⁺ hydrogen ions. The implanting of H⁺ ions is conducted for example with an implanting energy of between 20 and 250 keV and an implanting dose of approximately 3×10¹⁶ to 6×10¹⁶ atoms/cm², preferably 5.5×10¹⁶ atoms/cm². The implantation dose is chosen so that the concentration of H⁺ ions is sufficient to form and develop a weakened zone comprised of microcavities or platelets during a subsequent heat treatment step delimiting firstly a thin film or layer 4 defined between the weakened zone and a surface of the donor wafer in the upper region of the wafer 1, and secondly a portion 5 in the lower region of the wafer corresponding to the remainder of wafer 1.

Most of the implanted H⁺ ions are trapped at layer 3 forming stable complexes with the fluorine atoms present in the defects of layer 3. The formation/development of microcavities or platelets responsible for splitting is then delayed for as long as the implanted hydrogen is not available to pressurize the microcavities and platelets.

The donor wafer 1 is then molecular bonded onto a receiving wafer 6, e.g. a silicon wafer (step S3, FIG. 2C). The principle of molecular bonding is well known and need not be described in more detail. It is recalled that molecular bonding is based on the direct contacting of two surfaces, i.e. without using any specific material (glue, wax, low-melt metal, etc) the attraction forces between the two surfaces being sufficiently high to cause molecular bonding (bonding induced by all attraction forces, i.e., Van Der Waals forces, of electronic interaction between atoms or molecules of the two surfaces to be bonded).

As indicated above for FIG. 1, bonding energy increases with temperature, in particular due to the fact that over and above a certain temperature most bonds between the two contacted surfaces are covalent bonds. Also, as indicated in FIG. 1, bonding energy further increases with temperature, in particular over and above 550° C., when bonding is hydrophobic bonding i.e. when the surfaces of the wafers to be bonded are previously made hydrophobic. The surfaces of two wafers in silicon for example can be made hydrophobic by immersing the two wafers in an HF (hydrofluoric acid) chemical cleaning bath. The respective bonding surfaces 7 and 8 of the donor wafer 1 and receiving wafer 6 are therefore preferably given treatment prior to bonding to render them hydrophobic.

After the bonding step, the splitting step is performed of layer 4 from wafer 1, by application of heat treatment or splitting annealing which leads to splitting of the wafer at the H⁺ ion implantation area (step S4, FIG. 2D).

However, contrary to the temperatures usually encountered in heat schedules for splitting annealing in silicon wafers (temperatures typically ranging from 400 and 500° C.) the temperature of the heat schedule for splitting must, in this case, be higher owing to trapping of the hydrogen by fluorine. The application of a high heat schedule i.e. with temperatures higher than 500° C., is required to enable separation of the formed complexes (breaking of H—F bonds) leaving the implanted hydrogen available for the formation and development of microcavities/platelets which will cause splitting. The hydrogen can only fulfill its role as splitting species under the effect of heat treatment after it has been separated from the stable complexes. Since the hydrogen is only released over and above a temperature higher than temperatures usually used to cause splitting, the effects responsible for splitting between the layer to be transferred and the remainder of the donor wafer (crystal rearrangement and pressure effect in the microcavities/platelets) are also produced at higher temperatures than usual (temperatures over 500° C.). Therefore, the splitting of the layer to be transferred occurs at temperatures at which bonding energy is greater than with temperatures usually encountered for splitting heat treatments, making it possible to minimize defects at the bonding interface, to reduce and even eliminate diffusing species and thereby obtain a transferred layer of better quality.

A conventional polishing step (chemical-mechanical polishing) is then conducted to remove the disturbed layer and reduce the roughness of the fractured surface 9 of the transferred layer 4 (step S5, FIG. 2E). The disturbed layer may also be removed by selective chemical attack (etching) optionally followed by polishing to improve surface roughness. Heat treatment under hydrogen and/or argon can also be conducted either alone or in combination with polishing.

According to one variant of embodiment, the insertion in the wafer of one or more ion species able to react with the implanted species to form stable complexes, as described above, can be achieved by forming a doped layer in the donor wafer. This layer can be deposited or formed by ion implantation. Depositing of the doped layer can also be performed using PCVD for example (Plasma Chemical Vapor Deposition) or LPCVD (Low Pressure Chemical Vapor Deposition). With a donor wafer in silicon, the layer is doped with carbon, boron, phosphorus, arsenic, indium or gallium. Generally, the dopants are chosen in relation to the type of donor wafer to be treated.

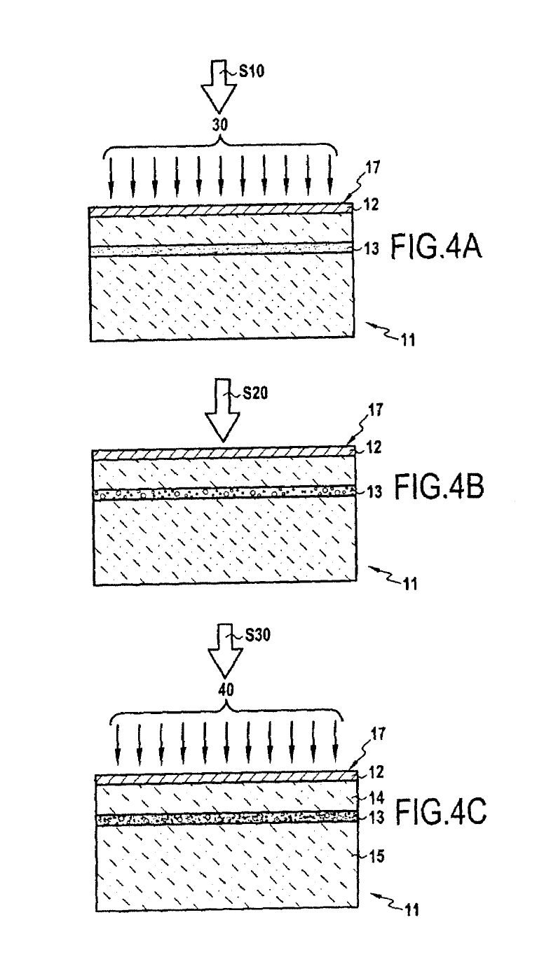

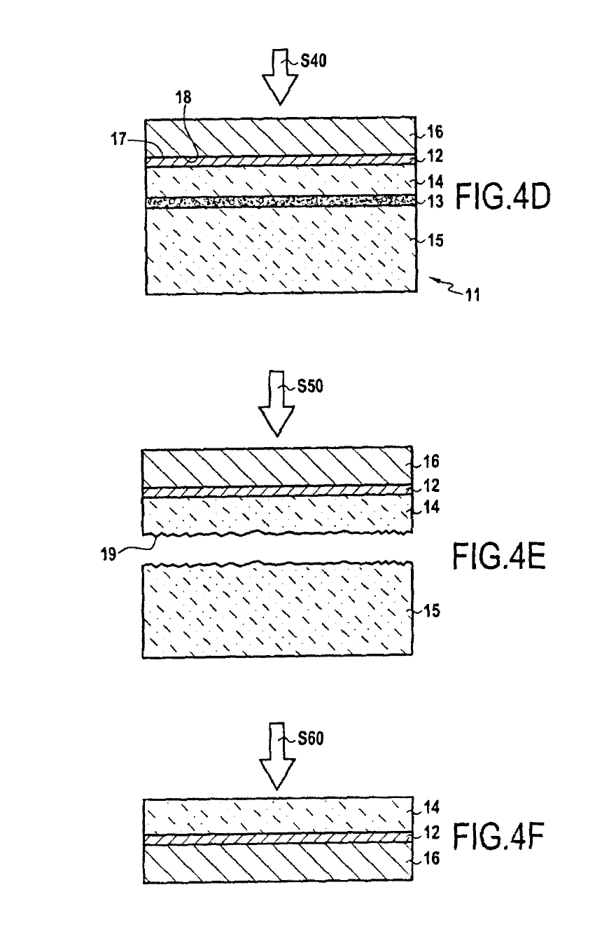

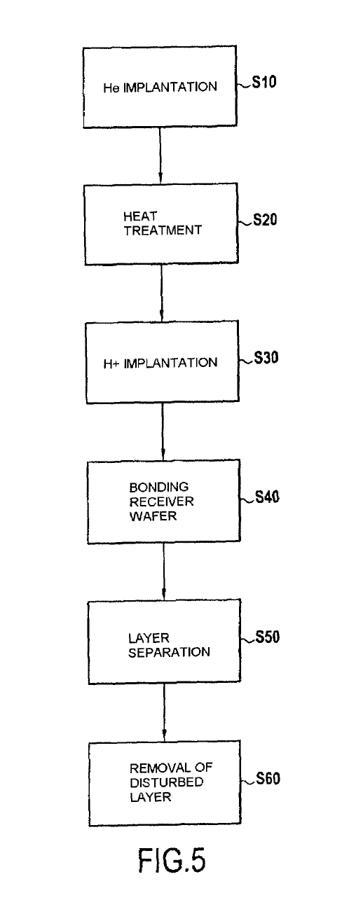

FIGS. 4A to 4F and 5 illustrate another embodiment of the layer transfer method according to the invention. This implementation differs from the one previously described in that instead of trapping the one or more implanted splitting species through the formation of stable complexes, these species are trapped in previously formed cavities before the splitting implantation step.

The starting substrate 11 is a wafer in monocrystalline silicon coated with a layer of silicon oxide (SiO₂) 12 obtained by thermal oxidation and having a thickness of approximately 300 Å.

During a first implantation step (step S10) the wafer 11 is first subjected to ion bombardment 30 with helium ions He through the planar face 17 of the wafer 11 comprising the SiO₂ layer 11. Implantation of He ions is conducted with an implanting energy of between 10 and 150 keV, here preferably 50 keV, and an implantation dose of between 1×10¹⁶ atoms/cm² and 5×10¹⁷ atoms/cm², in this case preferably 5×10¹⁶ atoms/cm². With these implanting conditions it is possible, at a determined depth in wafer 1, to create a He ion concentration layer 13 (FIG. 4A).

According to the invention, a heat treatment is then conducted to allow the development and/or formation of defects in the form of cavities at the He ion concentration layer 13 (step S20, FIG. 4B). These cavities will form reservoirs to provisionally trap the splitting species implanted during the following step. Heat treatment is conducted over a temperature range of 450° C. to 1000° C., in this case preferably 600° C., for a time of between 30 minutes to 1000 minutes, in this case preferably 1 hour.

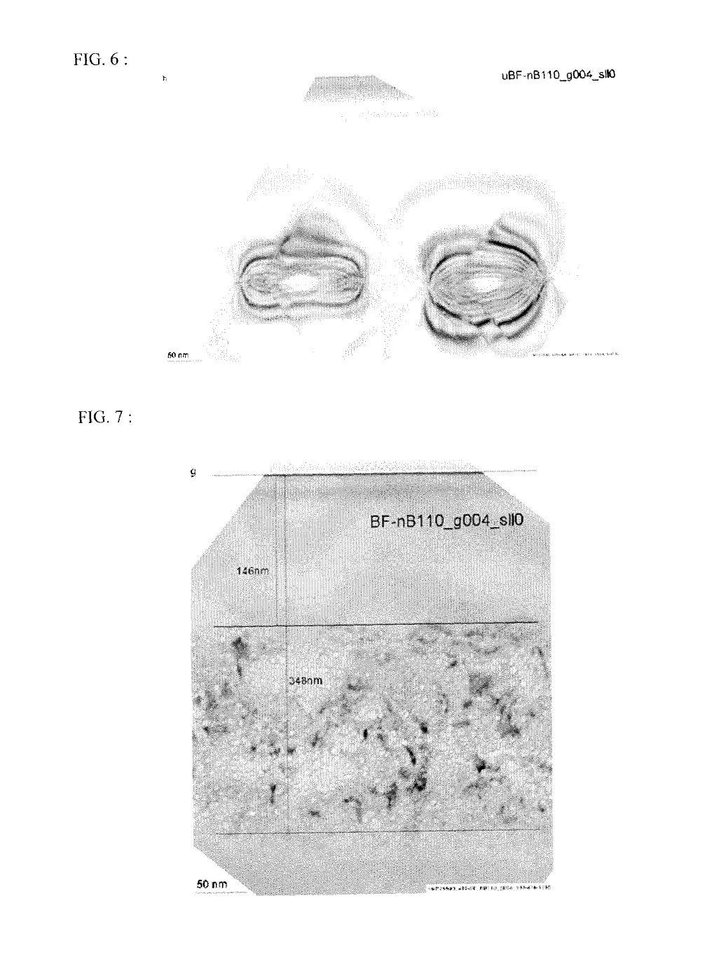

FIG. 6 shows cavities formed in a silicon wafer after helium implantation conducted with an implanting energy of approximately 50 keV and an implantation dose of approximately 1×10¹⁶ atoms/cm² followed by heat treatment at 600° C. for 1 hour.

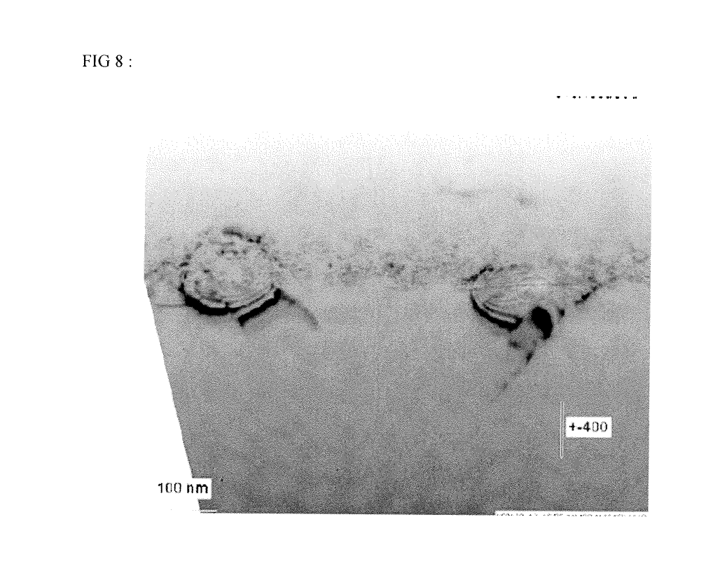

Implanting conditions and the heat schedule during formation of the trapping cavities are determined in relation to the type of implantation (species, implantation energy/dose) used to form the breaking layer for delamination, in order to promote maximum trapping reactions. Therefore, depending on the type of implantations to be performed for splitting, either a thick layer of small cavities/trapping reservoirs is made, or a thinner layer with larger cavities/trapping reservoirs. By way of example, FIG. 7 shows a silicon wafer comprising a thick layer (i.e. around 200 nm) containing numerous small cavities obtained after helium implantation performed with an implanting energy of around 50 keV and an implanting dose of around 5×10¹⁶ atoms/cm² followed by heat treatment conducted at 600° C. for 1 hour. The thickness of this layer and the size of the cavities are particularly well suited for trapping hydrogen ions implanted at an implanting energy of approximately 30 keV and an implanting dose of approximately 5.5×10¹⁶ atoms/cm².

Once the formation of trapping cavities is completed, the usual implantation step is performed to split the layer from the donor wafer (step S30, FIG. 4C). In this implantation step, the wafer 11 is subjected to ion bombardment 40 of H⁺ hydrogen ions. In the example under consideration, the implantation of H⁺ ions is conducted with an implanting energy of approximately 30 keV for example and an implanting dose of approximately 5.5×10¹⁶ atoms/cm². The implanting dose is chosen so that the concentration of H⁺ ions is sufficient to form and develop a weakened zone of microcavities or platelets during a subsequent heat treatment step delimiting firstly a thin layer or film 14 defined between the weakened zone and a surface of the donor wafer in the upper region of the wafer 11, and secondly a portion 15 in the lower region of the wafer corresponding to the remainder of wafer 11.

Most of the implanted H⁺ ions are trapped at layer 13 since they can easily house themselves in or around the previously created trapping cavities. FIG. 8 shows an area of a silicon wafer which has undergone implantation with hydrogen ions for subsequent splitting, conducted with an implanting energy of around 30 keV and an implanting dose of around 1×10¹⁶ atoms/cm², and after the formation of a line of cavities formed by implanting helium at an energy of around 50 keV and an implanting dose of around 1×10¹⁶ atoms/cm² followed by heat treatment conducted at 600° C. for 1 hour. It will be noted that the hydrogen ions are trapped in and between the cavities.

The donor wafer 11 is then molecular bonded onto a receiving substrate, e.g. a silicon wafer (step S40, FIG. 4D). The respective bonding surfaces 17 and 18 of the donor wafer 11 and receiving wafer 16 are preferably previously treated before bonding to render them hydrophobic.

After the bonding step, layer 14 is separated from wafer 11 by the application of splitting heat treatment leading to splitting of the wafer at the H⁺ ion implantation layer (step S50, FIG. 4E).

However, unlike the temperatures usually encountered in the heat schedules for splitting annealing in silicon type wafers (temperatures typically lying between 400 and 500° C.) the temperature of the heat schedule for splitting in this case must be higher to release the hydrogen trapped in the cavities. The application of a strong heat schedule, i.e. with temperatures over and above 500° C., required to make the implanted hydrogen available for the formation and development of the microcavities/platelets responsible for splitting, makes it possible to reinforce bonding energy at the time of splitting. Since the hydrogen is only released above a temperature higher than temperatures usually used to cause splitting, the effects responsible for delamination between the layer to be transferred and the remainder of the donor wafer (crystal rearrangement and pressure effect in the microcavities/platelets) are also produced at temperatures higher than usual (temperatures higher than 500° C.). Therefore, the splitting of the layer to be transferred occurs at temperatures at which bonding energy is stronger than with temperatures usually encountered for splitting heat treatments, allowing minimization of defects at the bonding interface, and reducing and even eliminating diffusing species and thereby obtaining a transferred layer of better quality.

A conventional polishing step (mechanical-chemical polishing) is then conducted to eliminate the disturbed layer and to reduce the roughness of the fractured surface 19 of transferred layer 14 (step S60, FIG. 4F). The disturbed layer can also be removed by selective chemical attack (etching) optionally followed by polishing to improve surface roughness and/or heat treatment under hydrogen and/or argon.

By increasing the temperature required to cause fracturing in the implanted donor wafer, the inventive method enables bonding energy to be reinforced at the time of splitting and allows defects in the resulting heterostructure to be minimized. The inventive method is advantageous in particular for the fabrication of heterostructures of SeOI type (Semi-conductor on insulator), in particular those containing a thin insulating oxide layer (UTBOX: Ultra Thin Buried Oxide Layer) or even not containing any oxide layer such as heterostructures of DSB type for example (Direct Silicon Bonding).

The temporary trapping of the implanted splitting species modifies degassing flow rates. By retaining a maximum amount of gas in the wafer before splitting, the flows that are “detrimental” to the quality of the bonding interface are reduced accordingly.

What is claimed is:

1. A method for transferring a thin layer from a donor wafer onto a receiving wafer comprising:
implanting at least one atomic species into the donor wafer to form a weakened zone therein, with the weakened zone being including microcavities or platelets therein, and the thin layer being defined between the weakened zone and a surface of the donor wafer;
molecular bonding of the surface of the donor wafer onto a surface of the receiving wafer;
splitting the thin layer at the zone of weakness by heating to a high temperature to transfer the thin layer to the receiving substrate; and
treating the donor wafer to block or limit the formation of microcavities or platelets by trapping the atoms of at least one of the implanted atomic species at least until a certain release temperature is reached during the splitting.

2. The method of claim 1, wherein the certain release temperature is at least 500° C.

3. The method of claim 2, wherein the treating is conducted before or after the implanting.

4. The method of claim 3, wherein the treating is conducted by inserting into the donor wafer at least one ion species that has the ability to react with the implanted atomic species.

5. The method of claim 4, wherein the inserting of the at least one ion species is performed by implanting.

6. The method of claim 5, wherein the ion species is fluorine, nitrogen or carbon.

7. The method of claim 4, wherein the inserting of at least one ion species is performed by forming a doped layer in the donor wafer prior to implanting the atomic species.

8. The method of claim 7, wherein the formation of the doped layer is made by depositing or implanting.

9. The method of claim 7, wherein the doped layer comprises at least one ion species of carbon, boron, phosphorus, arsenic, indium or gallium.

10. The method of claim 9, wherein the implanted atomic species is hydrogen.

11. The method of claim 10, wherein the heating during the splitting is conducted at a temperature of from approximately 550° C. to 800° C.

12. The method of claim 3, wherein the treating is performed by forming defects in the donor wafer.

13. The method of claim 12, wherein the defects are formed by implanting helium ions into the donor wafer, followed by heat treating the donor wafer to form cavities in the helium-implanted wafer.

14. The method of claim 13, wherein the helium ion implanting is performed with an implanting energy of between 10 and 150 keV and an implanting dose of between 1×10¹⁶ atoms/cm² and 5×10¹⁷ atoms/cm².

15. The method of claim 13, wherein the heat treating to form cavities is performed at a temperature of between 450° C. and 1000° C. for a time of between 30 minutes and 1000 minutes.

16. The method of claim 13, wherein during the splitting the heat treating is performed at a temperature of approximately 700° C. for a time of approximately 30 minutes.

17. The method of claim 13, wherein the implanted atomic species includes hydrogen and helium.

18. The method of claim 1, wherein during the bonding the surfaces of the donor wafer and of the receiving wafer to be bonded are previously treated to render them hydrophobic.

19. The method of claim 1, wherein the donor wafer is a semiconductor material.

20. The method of claim 1, wherein the donor wafer comprises a ferromagnetic, piezoelectric or pyroelectric material.
